(19) United States
(12) Patent Application Publication
(10) Pub. No.: US 2012/0190188 A1
(43) Pub. Date: Jul. 26, 2012

(54) METHOD FOR FILLING A GAP

(76) Inventors: Chao Zhao, Kessel-lo (BE); Wenwu Wang, Beijing (CN); Huicai Zhong, Beijing (CN)

(21) Appl. No.: 13/379,967

(22) PCT Filed: Feb. 28, 2011
(86) PCT No.: PCT/CN11/71360

§ 371 Date: Dec. 21, 2011

(30) Foreign Application Priority Data
Dec. 15, 2010 (CN) 201010590432.4

(51) Int. Cl. H01L 21/768

(52) U.S. Cl. 438/627; 257/E21.584

(57) ABSTRACT

A method for filling a gap includes: providing a semiconductor substrate, at least having an metal interconnect layer and an insulating dielectric layer on top of the underlying metal interconnect layer, the insulating dielectric layer having a gap; forming a diffusion bather layer and a seed layer sequentially in the gap and on a surface of the insulating dielectric layer outside the gap; forming a mask layer on a surface of the seed layer outside of the gap; and depositing a metal layer on the semiconductor substrate with the mask layer, the metal layer filling the gap.

### CROSS REFERENCE TO RELATED APPLICATIONS

The present application claims the priority of Chinese Patent Application No. 201010590432.4, entitled “Method for Filling a Gap”, and filed on Dec. 15, 2010, the entire disclosure of which is incorporated herein by reference.

### BACKGROUND OF THE INVENTION

1. Field of the Invention

The present invention relates to semiconductor technology, and particularly relates to a method for filling a gap.

2. Background of the Invention

With the increasing requirement for the high integrity and high performance of Ultra Large Scale Integrated circuit, semiconductor technology is developing towards 22 nm technology node and even smaller critical size. However, the operation speed of chips is obviously influenced by Resistance Capacitance Delay Time (RC Delay Time) caused by metal lines. Thus, in current semiconductor manufacturing technology, copper metal interconnect with lower resistivity is adopted to substitute traditional aluminum metal interconnect, so as to suppress RC delay.

Copper electroplating process has been widely applied to metal interconnect manufacturing process of Integrate Circuits (ICs) to fill a gap or a hole in a dielectric layer to manufacture copper metal line, so as to connect upper and lower metal line layers. Besides, in a contact plug structure neighboring device layers, the method of electroplating is also adopted for gap-filling if copper contact is used. In a three-dimension packaging technology achieved by Through Silicon Via (TSV), the method of electroplating is also required to fill the gap in preparation of TSV.

Currently, with the continuous scaling down of devices, sizes of semiconductor structures become smaller and smaller, resulting in more difficulty in filling a structure by electroplating. Particularly, if the semiconductor structure such as a TSV has a high aspect ratio, an overhang may be formed from a diffusion barrier layer and a copper seed layer, which are made by Physical Vapor Deposition (PVD), on top of the via. The overhang may be enlarged in the process of electroplating, which finally leads to close of the through-hole and results in void formed in the filled through-hole, and influences the reliability of a device.

FIG. 1 to FIG. 4 show a method for filling a gap in prior art. As illustrated in FIG. 1, an underlying metal interconnect layer 10 and a dielectric layer 12 with a through-hole 11 are formed on a semiconductor substrate. As shown in FIG. 2, a diffusion barrier layer 13 and a copper seed layer 14 are deposited on the semiconductor substrate by PVD. Conventionally, in order to avoid the diffusion of metal materials into the dielectric layer 12, the thickness of the diffusion bather layer 13 should not be less than a certain value (e.g., 6 nm). And when the size of the through-hole is less than a certain value (e.g., 20 nm), the aspect ratio for the deposition of the copper seed layer 14 becomes larger after the deposition of the diffusion bather layer 13. As shown in FIG. 3, a copper metal layer 15 is electroplated on the inner and outer surfaces of the copper seed layer 14. Because of the limited capability of the electroplating process for gap-filling, an overhang may be inevitably formed at the opening of the through-hole 11 while depositing the copper metal layer 15, which means more copper metal layer 15 may be deposited at the opening of the through-hole 11 compared with the inner part. As illustrated in FIG. 4, with the performing of the electroplating process, continuous deposition of the copper metal layer 15 may lead to too-early close of the through-hole 11, resulting in a void B formed in the through-hole 11 filled by the copper metal layer 15 and finally degrading the reliability of the device.

Besides, in the TSVs used in 3-Dimension (3D) packaging and gapes in advanced metal interconnect process, due to a high aspect ratio, similar gap-filling issues may also exist because of the overhang formed when depositing a diffusion barrier layer and a copper seed layer.

### SUMMARY OF THE INVENTION

An objection of the invention is to provide a method for filling a gap, which can avoid an existence of the void for gap-filling and improve the reliability of the circuit.

To achieve the objection, the present invention provides a method for filling a gap, including:

providing a semiconductor substrate, at least having an metal interconnect layer and an insulating dielectric layer on top of the underlying metal interconnect layer, the insulating dielectric layer having a gap;

forming a diffusion barrier layer and a seed layer sequentially in the gap and on a surface of the insulating dielectric layer outside the gap;

forming a mask layer on a surface of the seed layer outside the gap; and

platting a metal layer on the semiconductor substrate with the mask layer, the metal layer filling the gap.

While forming the mask layer on the surface of the seed layer outside the gap, a PVD process with beam-orientation control or a surface processing process is adopted, and in the above stated beam-orientation control, a direction of the beam deviates from normal of the semiconductor substrate is used.

Optionally, the mask layer has the characteristic of suppressing metal layer materials deposition on a surface of the mask layer during electroplating.

The mask layer further covers the overhang area of the gap

The mask layer is made of high resistance metal materials, semiconductor materials or dielectric materials.

Optionally, the mask layer comprises one of Ta and TaN, or a combination thereof.

The above stated surface processing is an oxygen ion implantation process and the material of the mask layer is copper oxide.

In the step of forming the mask layer on the surface of the seed layer outside the gap, the coverage of the mask layer is controlled by using suitable process time.

The gap can be one of a through-hole for a via, a trench and a through-hole for a TSV, or any combination thereof.

After filling the gap with the metal layer, the method further comprises a planarization process, which removes the metal layer, the seed layer and the diffusion barrier layer outside the gap to form a metal interconnect layer.

Compared with prior art, this invention has the following advantages.

In an embodiment of the invention, a method for filling a gap is provided. In the method, a diffusion barrier layer and a seed layer are formed sequentially in the gap and on the surface of the insulating dielectric layer outside the gap. And there is a mask layer formed on the surface of the seed layer outside the gap. Due to the suppression effect of the mask layer, the subsequent plating of Cu is not performed on the surface area in and outside the gap simultaneously. Instead, the metal layer is first deposited in the gap and then on the surface outside the gap, which can avoid the phenomenon of overhang, reduce or eliminate the possibility to produce voids, and hence increase the reliability of the circuits.

### BRIEF DESCRIPTION OF THE DRAWINGS

The above described and other features and advantages will become more apparent to those of ordinary skill in the art by describing in detail exemplary embodiments with reference to the attached drawings. The figures are not drawn to scale, and the emphasis is to illustrate the invention instead.

FIG. 1 to FIG. 4 are schematic structural diagrams of a method for filling a gap in the prior art;

FIG. 5 is a flow chart of a method for filling a gap according to a first embodiment of the present invention;

FIG. 6 to FIG. 12 are schematic structural diagrams of a method for filling a gap according to the first embodiment of the present invention; and

FIG. 13 is a schematic structural diagram of a method for filling a gap according to a second embodiment of the present invention.

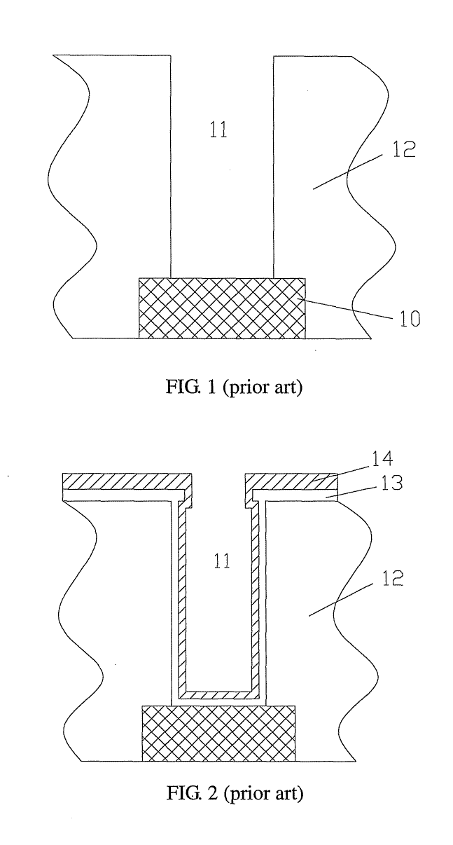

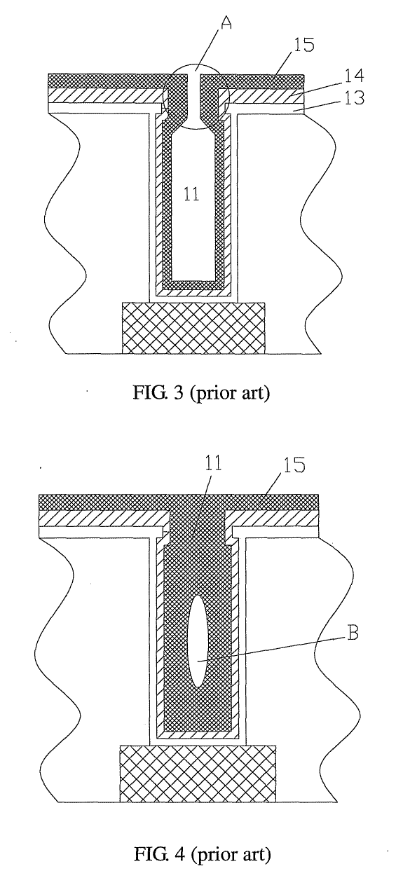

### DETAILED DESCRIPTION OF THE EMBODIMENTS

Hereafter, the present invention will be described in detail with reference to embodiments in conjunction with the accompanying drawings.

Although the present invention has been disclosed hereinafter as above with reference to preferred embodiments in detail to make it be fully understood, the present invention can be implemented in other embodiments which are different. Those skilled in the art can make similar deduction without departing from the scope of the present invention. Therefore, the present invention should not be limited to the embodiments disclosed hereunder.

Secondly, the invention is described in detail in conjunction with the accompanying drawings. When describing the embodiments of the invention in detail, the cross-section views of the device are not locally enlarged in proportion, and the schematic structural diagrams are just embodiments, which should not limit the scope of the present invention. Besides, the sizes of length, width and depth in three-dimensional space should be included in actual fabrication.

As described in the background technology of the invention, current semiconductor technology is developing towards 22 nm technology node and even smaller critical size, which may consequently lead to more circuit reliability issues. Therefore, focus is usually put on yield improvement in the art. The manufacture process of Back-end Of Line (BEOL) metal interconnect layer is often one of the factors which may cause decrease of circuit reliability.

The inventors of the present invention find, due to the small size and high aspect ratio of the gaps for BEOL metal interconnect layer and through-holes between layers, a diffusion barrier layer and a seed layer should be deposited before filling the gapes with metal materials by electroplating. An overhang may be inevitably formed on the opening while depositing a copper seed layer. During electroplating for further gap filling, the overhang may lead to close of the opening of the via before filling and the formation of voids, thus resulting in device reliability issues.

Based on the aforementioned issue, this invention provides a method for filling a gap. By selectively filling metal materials in the through-hole or gap, the overhang during electroplating can be avoided. Hereunder, the embodiments of the method for filling a gap will be described in detail in conjunction with the accompanying drawings.

### Embodiment 1

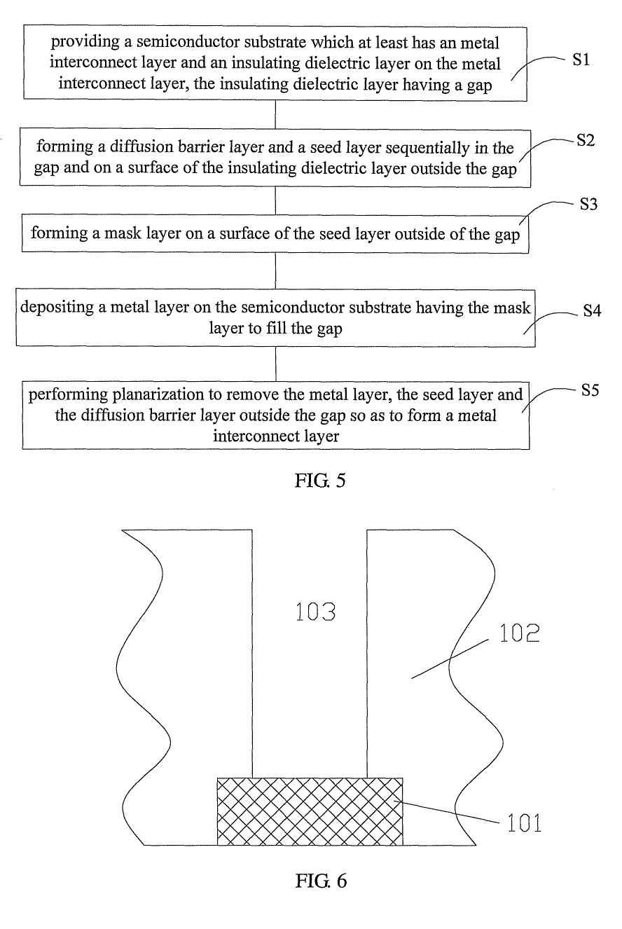

FIG. 5 is a schematic flow diagram of a method for filling a gap. FIG. 6 to FIG. 11 are structural diagrams schematically illustrating the method for filling the gap in the embodiment. In this embodiment, the through-hole between metal interconnect layers is filled, and therefore the through-hole is taken as an example of the gap.

As illustrated in the figures, the method for filling a gap includes the following steps.

In step S1, a semiconductor substrate is provided. Referring to FIG. 6, the semiconductor substrate comprises at least an underlying metal interconnect layer 101 and an upper insulating dielectric layer 102 on top of the underlying metal interconnect layer 101, wherein the insulating dielectric layer 102 has a gap 103. Here, the wording of “underlying” only indicates the relative position to the upper metal interconnect layer, and does not represent a first metal interconnect layer. The semiconductor substrate further includes logical devices, power devices and/or memory devices (not shown in the Figures), which are located under multiple metal interconnect layers. The underlying metal interconnect layer 101 is located on bottom of the gap 103, and the insulating dielectric layer 102 is located on sidewalls of the gap 103.

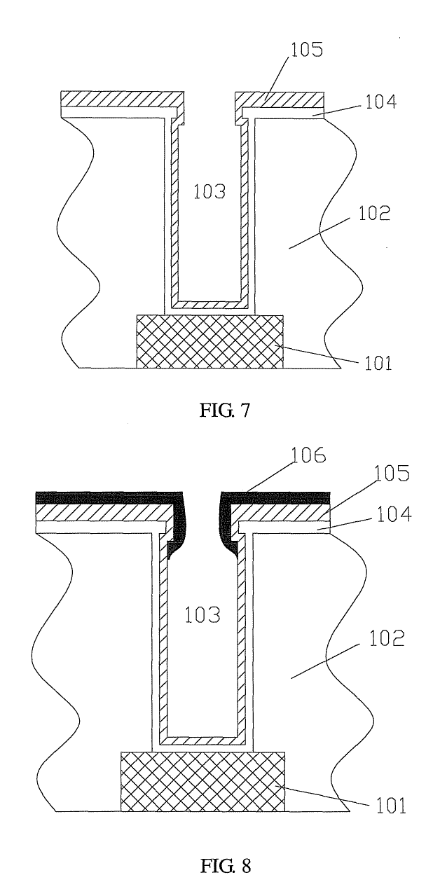

In step S2, as illustrated in FIG. 7, a diffusion barrier layer 104 and a seed layer 105 are sequentially formed in the gap 103 and on a surface of the insulating dielectric layer 102 outside the gap 103.

Specifically, the diffusion barrier layer 104 is deposited on the whole semiconductor substrate to cover the inner and outer surfaces of the gap 103 by PVD. The diffusion barrier layer 104 is usually made of refractory metals or alloy thereof. The materials of the diffusion barrier layer 104 include one of TaN, Ta, Ti and TiN, or any combination thereof. For example, a stacked diffusion barrier layer may be made of a Ti film and a TiN film formed thereon. Since the Ti film has certain capability of oxygen dissolution, it may deoxidize the underlying metal interconnect layer 101 when being in direct contact therewith, so as to reduce the contact resistance. And the TiN film can suppress or stop the diffusion of the metal material filled in the gap to the insulating dielectric layer 102. The diffusion barrier layer 104 has a thickness of about 10 nm. Chemical Vapor Deposition may also be adopted besides PVD.

The seed layer 105 has a thickness of about only several nanometers. The seed layer 105 can not only strengthen the adhesive force between the consequently filled metal layer and the diffusion barrier layer 104, but also can play a role of a nucleus for forming the metal layer. The material of the seed layer 105 is the same as or similar to that of the consequently filled metal layer. For example, the metal layer may be made of copper, and the seed layer 105 may also be made of copper or an alloy thereof. Optionally, the seed layer 105 can be fabricated by PVD.

In step S3, as shown in FIG. 8, a mask layer 106 is formed on a surface of the seed layer 106 outside the gap 103. In other words, the mask layer 106 is selectively deposited on the surface of the semiconductor substrate with the seed layer 105, so that the mask layer 106 is not formed on the surface in the gap 103, but only deposited on the surface outside the gap 103.

Specifically, the selective deposition of the mask layer 106 is achieved by adjusting the incidence angle of the beam and/or the processing time of PVD.

A PVD method with incline incident beam is adopted to deposit the mask layer 106. The direction of the beam deviates from the normal of the semiconductor substrate, which enables a coverage of the mask layer 106 only on the surface of the seed layer 105 (also field area) outside the gap 103 and avoids the coverage of the inner surface of the gap 103. Optionally, the deviation of the beam's direction from the normal of the semiconductor substrate is larger than 45 degrees.

Alternatively, the mask layer 106 may also be selectively deposited by adjusting deposition time. By means of the non-uniformity of the PVD method in the deposition process, the coverage range of the mask layer 106 may be controlled through adjusting deposition time. Generally speaking, the deposition rate of the mask layer on the inner surface of the gap 103 is much lower than that on the outer surface of the gap 103. Then, by referring to the performance and process parameters of the PVD equipment, the optimum deposition time can be deduced by the designed thickness of the mask layer 106. Optionally, if the thickness of the mask layer 106 is from 2 nm to 10 nm, the deposition time ranges from 0.5 s to 60 s. However, there is no limitation in this regard, and the thickness and deposition time of the mask layer can vary with different PVD equipments and process conditions.

The mask layer 106 also covers the overhang area of the gap 103. The overhang area is located on the connection area of the sidewall and outer surface of the gap 103.

The mask layer 106 comprises high resistance metal materials, semiconductor materials or dielectric materials. The high resistance metal materials comprise TaN, Ta, Ti, or TiN, or any combination thereof. The semiconductor materials comprise Si or Ge. The dielectric materials comprise SiO₂, SiC, SiNₓ, or SiON, or any combination thereof.

Preferably, the mask layer 106 comprises one of Ta and TaN, or a combination thereof. Most preferably, the mask layer 106 is Ta or Ti. In conventional front end of line process, the PVD method has been employed to deposit the Ta or Ti-based diffusion bather layer 104. Therefore, if the mask layer is formed of Ta or Ti, then there is no need to import new process chambers or precursors, which is beneficial for process integration and improving of the yield.

The mask layer 106 has a characteristic of suppressing metal materials to be deposited on the surface. Thus, there is little or even no metal layer deposited on the mask layer 106 during the electroplating process.

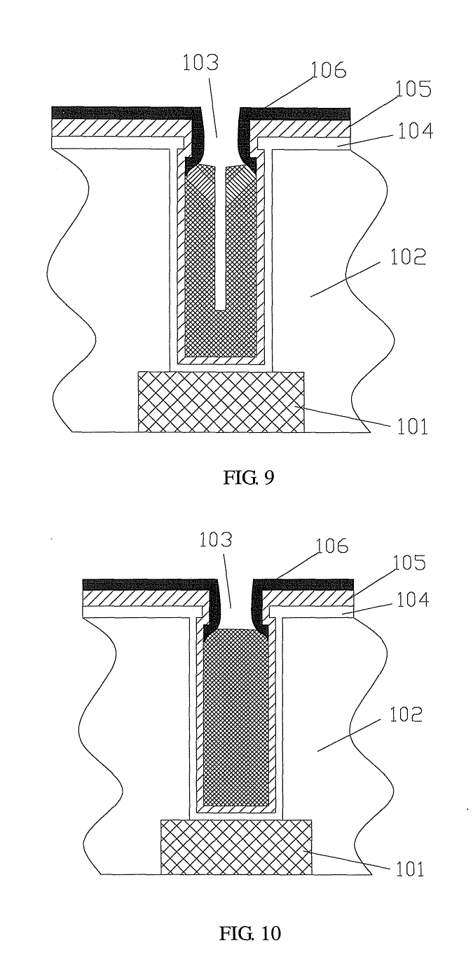

In step S4, as illustrated from FIG. 9 to FIG. 11, metal layer 107 is plated to cover the semiconductor substrate with the mask layer 106, and fill the gap 103.

Specifically, the metal layer 107 is deposited on the surface of the semiconductor substrate by the electroplating process with the mask layer 106 as a barrier layer. The metal layer 107 is made of copper.

As shown in FIG. 9, because of the protection of the mask layer 106 or because there is no seed layer on the mask layer 106 for forming the nuclei of the metal layer 107, the metal layer 107 is only formed in the gap 103 but not on the overhang area and the outer surface of the gap at the beginning of the deposition. With the proceeding of the deposition, the space left in the gap 103 becomes smaller and smaller.

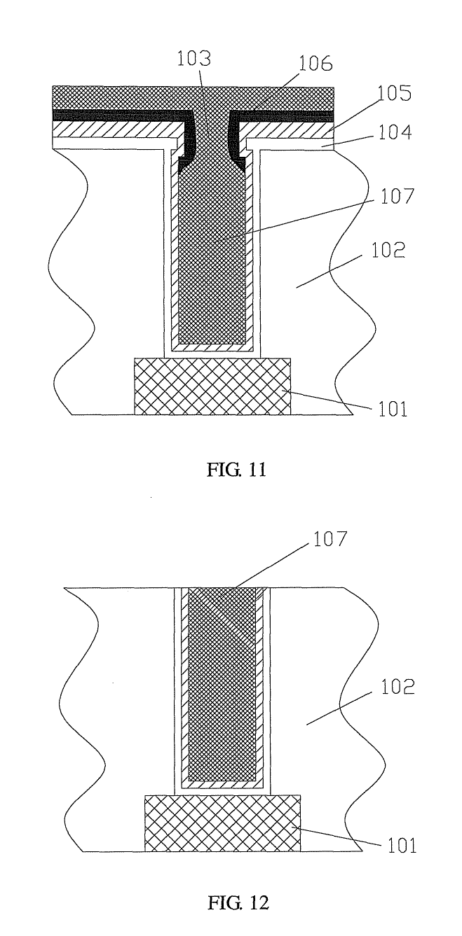

As shown in FIG. 10, the inner space of the gap 103 is completely filled by the metal layer 107. With the continuing of the electroplating process, the metal layer 107 covers the overhang area and the outer surface of the gap 103 until a total coverage of the exposed surface of the semiconductor substrate, as illustrated in FIG. 11.

In another embodiment of the invention, after depositing the metal layer 107 in the gap 103, the method further comprises step S5: performing a planarization process to remove the metal layer 107, the seed layer 105 and the diffusion barrier layer 104 outside the gap 103 so as to form a metal interconnect layer.

As shown in FIG. 12, the planarization process is preferably a Chemical Mechanical Polishing (CMP) method. During the CMP process, because the mask layer 106 has the characteristic of suppressing metal layer materials to deposit on the surface, there is no metal layer 107 deposited on the surface of the mask layer 106 during the electroplating process or only a very thin metal layer 107 is deposited. Thus, the metal layer 107 can be easily polished. After the removal of the diffusion barrier layer 104 by CMP, the outer surface of the gap 103 is the insulating dielectric layer 102, and the metal interconnect layer is formed in the gap 103 so as to form an electrical connection with the underlying metal interconnect layer 101.

In the present invention, a method for filling a gap is provided. In the method, a diffusion barrier layer and a seed layer are sequentially formed on a surface of the insulating dielectric layer in and outside the gap. And there is a mask layer formed on the surface of the seed layer outside the gap. By the protection of the mask layer, the subsequent deposition of a metal layer on the semiconductor substrate is not performed simultaneously on the surface in and outside the gap. Instead, the metal layer is first deposited in the gap and then on the surface outside the gap, which can avoid overhang and reduce/eliminate the generation of voids, and hence increase the reliability of the circuits.

In the embodiment, the gap is a through-hole. In other embodiments, the gap may also be other semiconductor structures with a large aspect ratio. The gap in other embodiments of the invention can also be a trench, a TSV, or any combination of a through-hole, a trench and a TSV.

In the step of forming a mask layer on the surface outside of the gap, directional beam is employed in the PVD method in the embodiment. As a mater of fact, a surface processing process can also be employed to form the mask layer, which will be elucidated in the following embodiment.

### Embodiment 2

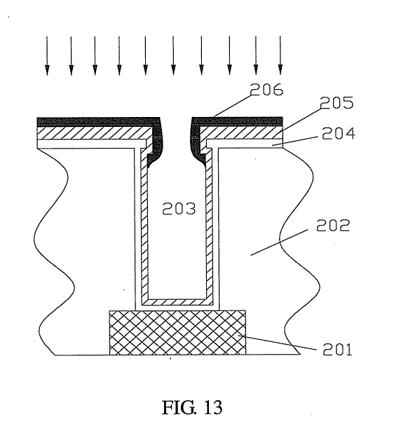

FIG. 13 is a schematic structural diagram of a method for filling a gap according to a second embodiment of the present invention. The method for filling a gap includes:

providing a semiconductor substrate, which at least has an underlying metal interconnect layer and an upper insulating dielectric layer on the underlying metal interconnect layer, the insulating dielectric layer having a gap;

forming a diffusion barrier layer and a seed layer sequentially in the gap and on a surface of the insulating dielectric layer outside the gap;

forming a mask layer on a surface of the seed layer outside the gap;

depositing a metal layer on the semiconductor substrate with the mask layer, and the metal layer being filled in the gap; and

performing a planarization process to remove the metal layer, the seed layer and the diffusion barrier layer outside the gap so as to form a metal interconnect layer.

The difference between the above steps in this embodiment and the first embodiment is that a mask layer 206 is formed on the surface of the copper seed layer 205 outside of the gap 203 by a surface processing process. Preferably, an ion implantation processing is performed to modify the surface of the copper seed layer 205, which makes it difficult to deposit metal layer on the surface or even no metal layer deposition can be formed.

For example, oxygen ion implantation is performed on the surface of the copper seed layer 205 to form the mask layer 206 of a copper oxide. Then, the subsequently deposited copper metal layer (not shown in the Figure) can be firstly deposited in the gap 203 rather than on the surface of the mask layer 206.

The depth of the oxygen ion implantation may be determined according to the thickness of the copper seed layer 205. For example, if the thickness of the copper seed layer ranges from about 5 nm to about 10 nm, the depth of the oxygen ion implantation may be about 5 nm to about 10 nm. Besides, it is necessary to control the direction of the ion beam during the implanting process. The direction of the beam may deviate from the normal of the semiconductor substrate so that the mask layer 206 only covers the copper seed layer 205 (also referred as field area) outside of the gap 203 and avoids coverage of the inner surface of the gap 203. Optionally, the deviation of the beam direction from the normal of the semiconductor substrate is beyond 45 degrees.

Other steps of the embodiment are similar to the first embodiment and will not be elucidated here.

In another embodiment of this invention, the mask layer can also be a stacked layer including a photo resist layer. For example, a hard mask layer, an anti-reflection layer and a photo resist layer may be sequentially formed on top of the seed layer. The position of the gap can be more accurately defined by forming a mask layer with a gap pattern by means of lithography and exposure, which increases the reliability of the process. However, the cost control is not as good as that in the first and the second embodiments because of the additional lithography process.

The aforementioned are only exemplary embodiments of the invention, and does not impose any formal limitation to the invention. Though the process for filling a gap between metal interconnect layers is taken as examples in the above embodiments, the provided method for filling a gap in the invention can also be applied to the TSV in 3D package and gapes in advanced metal interconnect process.

Although the present invention has been disclosed as above with reference to preferred embodiments, it is not intended to limit the present invention. Those skilled in the art may modify and vary the embodiments without departing from the spirit and scope of the present invention. Accordingly, the scope of the present invention shall be defined in the appended claims.

The embodiments in the invention are described in a step-up way. Each embodiment emphasizes the difference from the others and similar part between each embodiment can be referred from each other. The above description of the embodiments is disclosed such that those skilled in the art can realize or use the invention. Multiple modifications to these embodiments are obvious for those skilled in the art. The principle defined in this specification can be achieved in other embodiments without departure from the spirit or scope of the invention. Therefore, the invention will not be limited to these embodiments, but should be interpreted in accordance with the widest range consistent to the disclosed principles and novel characteristics of this specification.

1. A method for filling a gap, comprising:
providing a semiconductor substrate which at least has an metal interconnect layer and an insulating dielectric layer on the metal interconnect layer, the insulating dielectric layer having a gap;
forming a diffusion barrier layer and a seed layer sequentially in the gap and on a surface of the insulating dielectric layer outside the gap;
forming a mask layer on a surface of the seed layer outside of the gap; and
depositing a metal layer on the semiconductor substrate having the mask layer to fill the gap.

2. The method for filling a gap of claim 1, wherein in the step of forming a mask layer on a surface of the seed layer outside the gap, a directional beam PVD or a surface processing process is performed, and a direction of the beam deviates from the normal of the semiconductor substrate.

3. The method for filling a gap of claim 2, wherein the mask layer has the characteristic of suppressing metal layer materials to be deposited on a surface of the mask layer.

4. The method for filling a gap of claim 1, wherein the mask layer further covers a overhang of the gap.

5. The method for filling a gap of claim 1, wherein the mask layer is made of high resistance metal materials, semiconductor materials or dielectric materials.

6. The method for filling a gap of claim 1, wherein the mask layer comprises Ta, TaN, or a combination thereof.

7. The method for filling a gap of claim 2, wherein the surface processing process is an oxygen ion implantation process and the mask layer is made of copper oxide.

8. The method for filling a gap of claim 1, wherein in the step of forming a mask layer on a surface of the seed layer outside the gap, the mask layer is formed only on the surface of the seed layer outside the gap by adjusting process time.

9. The method for filling a gap of claim 1, wherein the gap is one of a through-hole for a via, a trench and a through-hole for a TSV, or any combination thereof.

10. The method for filling a gap of claim 1, wherein the gap is filled with the metal layer, and the method further comprises performing planarization to remove the metal layer, the seed layer and the diffusion barrier layer outside the gap so as to form a metal interconnect layer.

11. The method for filling a gap of claim 9, wherein the gap is filled with the metal layer, and the method further comprises performing planarization to remove the metal layer, the seed layer and the diffusion barrier layer outside the gap so as to form a metal interconnect layer.
